(19) United States
(12) Patent Application Publication
(10) Pub. No.: US 2008/0068547 A1
(43) Pub. Date: Mar. 20, 2008

(54) Liquid crystal display panel and method of making the same

(75) Inventor: Hiromitsu Tanaka, Kawasaki (JP)

Correspondence Address: YOUNG & THOMPSON, 745 SOUTH 23RD STREET, 2ND FLOOR, ARLINGTON, VA, 22202, US

(73) Assignee: NEC LCD TECHNOLOGIES, LTD., KAWASAKI (JP)

(21) Appl. No.: 11/896,380

(22) Filed: Aug. 31, 2007

(30) Foreign Application Priority Data
Sep. 20, 2006 (JP) 2006-253949

(51) Int. Cl. G02F 1/1337; H01L 21/02

(52) U.S. Cl. 349/123; 438/30; 257/E21.536

(57) ABSTRACT

Recesses and protrusions are formed on the surface of an orientation film that is formed on a substrate of the liquid crystal display panel comprising a glass substrate 1 and a TFT 2. An ion beam is radiated on the entire surface of the uneven orientation film to reach the saturating condition, thereby increasing the effective orientation surface area. If there are large bumps on the surface of the orientation film 3 that is radiated by an ion beam from an ion beam source to cause shadow portions, the ion beam is radiated on the shadow portions from the opposite direction. In order to form recesses and protrusions on the orientation film, it is preferable to have an orientation plate mesh structure having rough mesh depth and pitch and a particular solvent composition that easily causes recesses and protrusions on the surface chosen as the orientation material.

### INCORPORATION BY REFERENCE

This application is based upon and claims the benefit of priority from Japanese patent application no. 2006-253949, filed on Sep. 20, 2006, the disclosure of which is incorporated herein its entirety by reference.

### TECHNICAL FIELD

This invention relates to a liquid crystal display panel and a method of making liquid crystal display panel, more specifically to a liquid crystal display panel and a method of making liquid crystal display panel in which orientation processing is carried out on the surface of an orientation film using ion beam.

### BACKGROUND ART

A conventional method of forming an orientation film on a TFT (Thin Film Transistors) for improving orientation of a liquid crystal display panel is to rub the panel with a cloth. However, such conventional method has a problem in that it not only requires a washing step of the orientation film for removing impurities derived from the rubbing process but it also leaves a so-called “mesh” caused by scratching, thereby causing color irregularity so-called “vertical stripes”. In light of such problem, an ion beam radiation method has been proposed to form an orientation film of light sensitive polymer on a TFT and radiate an ion beam in a slanted direction for causing inclined orientation at a light sensitive portion of the light sensitive polymeric film in a non-contacting manner as disclosed in, for example, Japanese patent publication no. 2006-119403 entitled “Electro-optical Device, Method of Making the Same and Electronic Equipment”.

Now, the technique using the abovementioned ion beam radiation method will be described with reference to FIG. 3. FIG. 3 is a simplified schematic to show the film surface condition of the orientation film according to the conventional method of making liquid crystal display panel. FIG. 3(A) is a cross section view to show the cross sectional shape of such liquid crystal display panel. FIG. 3(B) is a perspective view to show a surface layer of an orientation plate on which an orientation material is printed. FIG. 3(C) is a magnified view of the surface layer of the orientation plate for schematically showing a mesh pattern of the orientation plate. As shown in FIG. 3(A), the liquid crystal display panel is fabricated in sequential steps of forming a TFT 2 on a glass substrate 1, coating an orientation material on the TFT 2 in the thickness of 500□700□ for forming an orientation film 3C in such a manner that the surface layer thereof is flat, and radiating an ion beam onto the flat surface layer at a constant angle to form an ion beam radiation layer 4C in the thickness of 20□30□.

As shown in FIG. 3(B), the surface of the orientation plate onto which an ion beam is radiated is a mesh-shaped surface layer of the orientation plate such as the orientation plate mesh 5C. As shown in FIG. 3(C), the mesh depth 6C that represents the height of protrusions of the orientation plate mesh 5C in the conventional orientation plate is uniform over the entire surface and shallow. Also, the distance between adjacent protrusions of the orientation plate mesh 5C is relatively large as shown by the mesh pitch 7C.

As a result, in case of fabricating the orientation film 3C by coating an orientation material on the TFT 2 formed on the glass substrate 1, since the orientation plate is coated uniformly over the entire surface and to a uniform thickness, the ion beam radiation layer 4C is formed with a flat surface layer of the orientation film 3C onto which an ion beam is radiated, thereby restricting the effective orientation area for the ion beam.

As described hereinabove, in the conventional method of making orientation film for liquid crystal display panel by the ion beam radiation method, since the orientation film is made by coating an orientation material over the entire surface of the TFT and to a uniform thickness, the surface layer of the orientation film onto which an ion beam is radiated is flat, thereby restricting the effective orientation area of the ion beam. Specifically, the conventional method has the following problems:

A first problem is that the effective area contributing to the ion beam orientation is small. As a result, it is difficult to have a large orientation regulation force for orienting the liquid crystal to an intended direction by the ion beam radiation, thereby unavoidably causing residual image.

A second problem is that the orientation regulation force by the ion beam radiation method is inherently weak as compared to the conventional rubbing method. This means that the residual image of displayed image tends to clearly exist.

In other words, the orientation regulation force by the ion beam radiation method has a limitation relative to radiation intensity. There is no possibility of further enhancing the orientation regulation force even if radiating the beam in excess of a certain amount. On the other hand, the area where the ion beam is radiated is no more than the display area. This makes it difficult to increase the orientation regulation force and thus causes residual image. Moreover, since the orientation regulation force by the ion beam radiation method is inherently lower as compared to the conventional rubbing method, there are possibilities of clearly encountering a residual image problem.

### SUMMARY

In light of the above circumstances, there is a need to improve the aforementioned problems relating to the surface of the orientation film made by the ion beam radiation method. It is therefore a primary object of this invention to provide a liquid crystal display device and a method of making the same by forming recesses and protrusions on the surface of the orientation film onto which the ion beam is radiated for improving the orientation regulation force by increasing the effective area to be radiated by the ion beam, thereby minimizing the possibility of causing residual image and thus improving display image quality.

In other words, in order to solve the aforementioned problems associated with the prior art, this invention features the formation of recesses and protrusions on the surface of the substrate onto which the ion beam is radiated so that the entire uneven surface with recesses and protrusions is radiated by the ion beam up to the saturating condition. In this manner, it is possible to provide a method of making liquid crystal display device and a liquid crystal display device made by such method in which the effective orientation surface area and the orientation regulation force are increased, thereby effective to minimize the residual image problem.

According to an aspect of the present invention, there is provided (1) a method of making liquid crystal display panel including orientation processing by radiating an ion beam onto an orientation film made on a substrate for the liquid crystal display panel, comprising the steps of: forming recesses and protrusions on the surface of the orientation film that is radiated by the ion beam; and radiating the ion beam onto the entire surface of the orientation film having recesses and protrusions to reach the saturating condition; thereby increasing the effective orientation surface area.

Other exemplary embodiments of the present invention are expressed as follows:

(2) A method of making liquid crystal display panel of the above (1), wherein if there are large bumps on the surface of the orientation film onto which the ion beam is radiated to cause shadowed portions to an ion beam source, the ion beam is radiated to the shadowed portions from the opposite direction.

(3) A method of making liquid crystal display panel of the above (1), wherein the orientation film is formed in a mesh structure having a mesh depth larger than a predetermined value and a mesh pitch larger than a predetermined pitch, an orientation material for forming the orientation film is chosen to have solvent composition that is easy to form recesses and protrusions on the surface, and recesses and protrusions are formed on the surface of the orientation film.

(4) A method of making liquid crystal display panel of claim 1, wherein either solvent concentration of a leveling agent to be used for the orientation material is set to lower than a predetermined threshold value or concentration of the primary material composing the orientation material is set to higher than a predetermined threshold value.

(5) A method of making liquid crystal display panel of the above (1), wherein recesses and protrusions on the surface of the orientation film are formed by mixing the orientation material for forming the orientation film with solid particles that are sufficiently smaller than a cell gap of the orientation material.

(6) A method of making liquid crystal display panel including orientation processing by radiating an ion beam onto an orientation film made on a substrate for the liquid crystal display panel, comprising the steps of:

forming recesses and protrusions on the surface of the orientation film that is radiated by the ion beam; and

radiating the ion beam onto the entire surface of the orientation film having recesses and protrusions to reach the saturating condition to increase the effective orientation surface area;

forming recesses and protrusions on the surface of the orientation film by mixing the orientation material for forming the orientation film with solid particles that are sufficiently smaller than a cell gap of the orientation material;

adjusting the surface condition and shape of the solid particles and the surface tension and concentration of the orientation material that the surface of each solid particle is sufficiently covered with the orientation material.

(7) A method of making liquid crystal display panel of the above (1), wherein a photo lithography processing is applied to a glass substrate, a liquid crystal device layer or a transparent film constituting the liquid crystal display panel to form bumps on the surface of the liquid crystal display panel, thereby forming recesses and protrusions on the surface of the orientation film that is formed on a substrate of the liquid crystal display panel.

(8) A method of making liquid crystal display panel of the above (1), wherein a photo lithography processing is applied to a glass substrate, a liquid crystal device layer or a transparent film constituting the liquid crystal display panel to form bumps on the surface of the liquid crystal display panel, thereby forming recesses and protrusions on the surface of the orientation film that is formed on a substrate of the liquid crystal display panel, the etching process being applied so that drain areas or gate areas on a liquid crystal device layer constituting the substrate for the liquid crystal display panel being formed in a protruding structure and pixel display area being formed in a recessed or flat structure.

(9) A liquid crystal display panel made by orientation processing that radiates an ion beam onto an orientation film that is formed on a substrate for liquid crystal display panel,

wherein the surface of the orientation film that is radiated by the ion beam is uneven to have recesses and protrusions, and the ion beam is radiated onto the entire surface of the uneven orientation film to reach the saturating condition.

(10) A liquid crystal display panel of claim 9, wherein the orientation film is made in an orientation plate mesh structure to have a mesh depth deeper than a predetermined depth and a mesh pitch narrower than a predetermined pitch, and the orientation material to form the orientation film comprises a solvent composition that is easy to form recesses and protrusions on the surface.

(11) A liquid crystal display panel of claim 9, wherein the orientation film is made from an orientation material mixed with solid particles that are sufficiently smaller than a cell gap of the orientation material.

(12) A liquid crystal display panel of claim 9, wherein bumps are formed on a glass substrate, a liquid crystal device layer or a transparent film for forming a substrate of the liquid crystal display panel.

A method of making liquid crystal display device and a liquid crystal display device of the present invention exhibit the following practical advantages:

That is, the present invention is able to increase the orientation regulation force and suppress display residual image to occur. This is because recesses and protrusions are formed on the surface of the orientation film on the substrate onto which the ion beam is radiated, thereby improving the orientation regulation force as a result of increasing the ion beam radiation area on the orientation film per unit area of the ion beam.

It is to be noted in this invention that if the ion beam is not sufficiently radiated because of shadow portions to an ion beam source as a result of increased bumps or step portions on the substrate, it is possible to rotate the angle of radiation from the ion beam radiation source so that an ion beam radiation layer is formed at the shadowed portions by radiating from the opposite direction, thereby enabling to provide sufficient orientation regulation force.

### BRIEF DESCRIPTION OF THE DRAWINGS

The objects and advantages of this invention will become apparent from the following descriptions on embodiments of this invention with reference to the accompanying drawings, in which:

FIG. 1 is a simplified illustration of the surface condition of an orientation film according to one exemplary liquid crystal display device that is made based upon a method of making liquid crystal display device of the present invention;

FIG. 2 is a simplified illustration of the surface condition of an orientation film according to another exemplary liquid crystal display device that is made based upon a method of making liquid crystal display device of this invention; and

FIG. 3 is a simplified illustration of the surface condition of an orientation film of a conventional liquid crystal display panel.

### EXEMPLARY EMBODIMENTS

Now, exemplary methods of making liquid crystal display panel and liquid crystal display panels of the present invention will be described in detail with reference to the accompanying drawings.

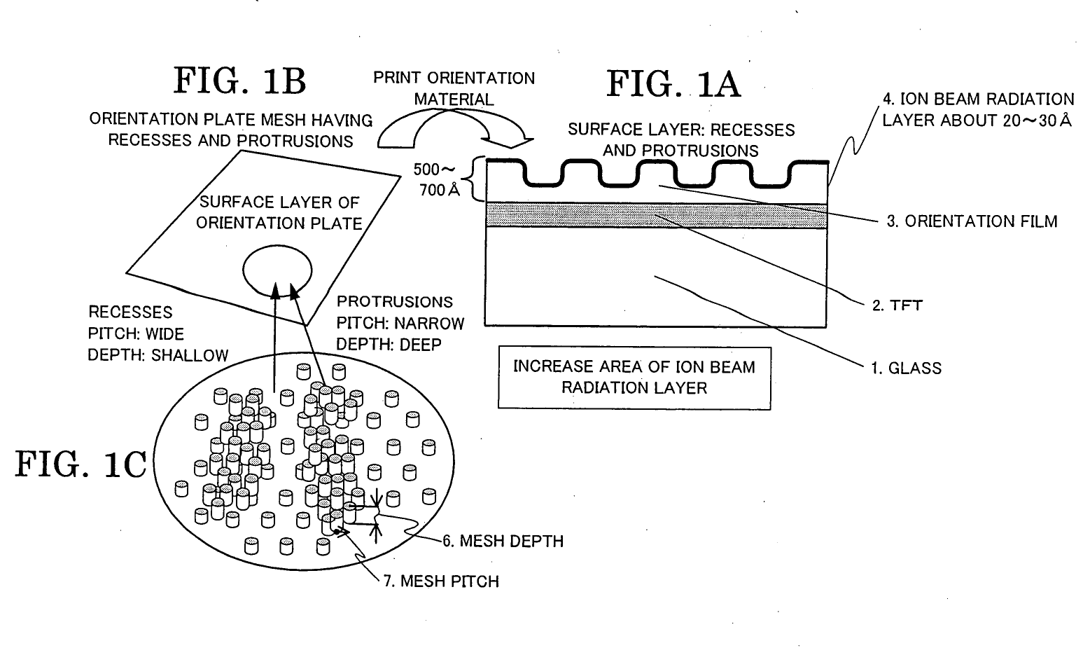

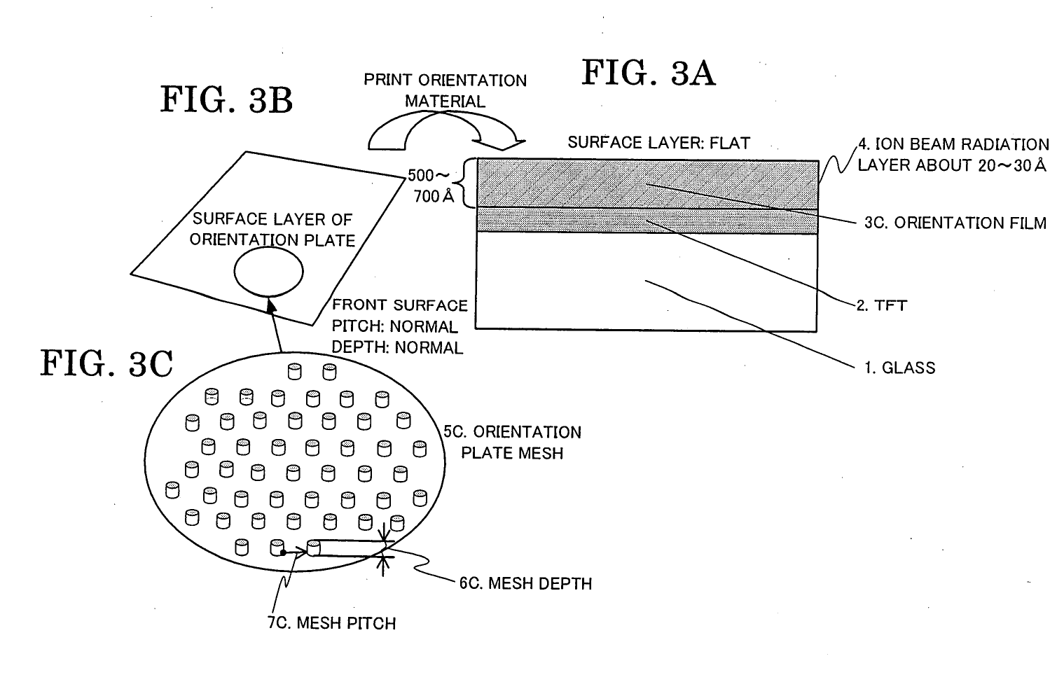

FIG. 1 is a simplified illustration of an orientation film condition of a liquid crystal display panel that is made by a first exemplary method of making liquid crystal display panel according to this invention. In this exemplary embodiment, recesses and protrusions are formed in an orientation film on a substrate of such liquid crystal display panel. It is to be noted that FIG. 1 is a similar illustration to FIG. 3 as described hereinabove in connection with prior art. FIG. 1(A) is a cross section view to show a cross sectional shape of the liquid crystal display panel. FIG. 1(B) is a perspective view illustrating the surface layer of an orientation plate on which an orientation material is coated. FIG. 1(C) is a magnified view of the surface layer of the orientation plate in which a mesh pattern of the orientation plate is schematically shown. In the following description of the exemplary embodiment, it is described on an example of using a TFT (Thin Film Transistors) as a liquid crystal element for the liquid crystal display of this invention.

As shown in FIG. 1(A), the liquid crystal display panel of this invention is made by forming a 500˜700□ thick orientation film 3 by coating an orientation material on a TFT 2 that is first formed on a glass substrate 1 in the same manner as in FIG. 3(A). However, the orientation film 3 is different from the one in FIG. 3(A) in that an orientation plate mesh having recesses and protrusions is coated, thereby forming recesses and protrusions as a surface layer. Subsequently, an ion beam is radiated at a certain angle onto the entire surface of the uneven (non flat) orientation film 3C until it reaches the saturating condition. For portions that are shadowing to the ion beam source, the radiation angle of the ion beam source is rotated to radiate from the opposite direction, thereby forming an ion beam radiation layer 4 even at the shadowing portions to the ion beam source. As a result, the 20˜30□ thick ion beam radiation layer 4 is formed over the entire area of the surface layer on the orientation film 3.

The surface of the orientation plate onto which the ion beam is radiated is a mesh-like surface layer of an orientation plate mesh 5 as shown in FIG. 1(B). However, unlike the shape of the orientation plate mesh 5C as shown in FIG. 3, the mesh depth 6 representing the height of the protrusions of the orientation plate mesh 5 is deeper than that of the orientation plate mesh 5C over the entire surface and the mesh pitch 7 representing the distance between adjacent protrusions of the orientation plate mesh 5 is narrower than that of the orientation plate mesh 5C.

Describing more in detail with reference to FIG. 1, the method of making liquid crystal display panel of this invention employs an ion beam radiation method in which recesses and protrusions are formed on the substrate of the liquid crystal display panel including the glass substrate 1 and the TFT 2 and the entire surface layer of the orientation film 3 having such recesses and protrusions formed thereon is radiated by an ion beam in a particular direction until the saturating condition. As a result, the effective orientation surface area on the substrate that is formed as the ion beam radiation layer 4 is increased for enhancing the orientation regulation force, thereby achieving an advantageous structure for minimizing residual image.

It is to be noted in this invention that if there are large bumps or step portion where sufficient ion beam is not radiated because of shadowing to the ion beam source, the angle of radiation of the ion beam from the ion beam radiation source may be rotated for radiating also from the opposite direction as mentioned hereinabove, thereby obtaining a sufficient orientation regulation force by forming the ion beam radiation layer 4 at the shadowing portions.

### First Exemplary Embodiment

Now, some exemplary embodiments of the method of making liquid crystal display panel will be described. Firstly, with reference to FIG. 1, a description will be made on a first exemplary embodiment of a method of forming recesses and protrusions by changing a mesh condition in forming the orientation film on the substrate, i.e., a mesh condition of the orientation plate. In a conventional orientation printing on the substrate, tuning between the orientation plate and the orientation material is made in order to minimize unevenness (recesses and protrusions) on the substrate surface. On the contrary to the prior art, in this exemplary embodiment, unevenness (recesses and protrusions) is intentionally created on the substrate surface at the time of orientation printing by roughing mesh depth and mesh pitch of the orientation plate. In other words, the mesh depth is made deeper than a predetermined mesh depth and the mesh pitch is made narrower than a predetermined pitch. Moreover, used is an orientation material of a particular solvent composition to cause surface irregularity, i.e., a solvent composition to reduce leveling is chosen.

It is to be noted here that, in an orientation condition by ion beam, the conventional structure to reduce unevenness on the substrate surface encounters a certain saturation relative to accumulated intensity of ion beam radiation, thereby reaching an upper limit in the orientation regulation force. However, in this exemplary embodiment, since recesses and protrusions are formed on the substrate surface, it is possible to radiate ion beam over the entire substrate surface until reaching the saturating condition, thereby enabling to expand the effective orientation surface area, increasing the orientation regulation force, and providing an advantageous structure against long-term residual image.

Attention should be paid to the fact that the radiation angle or the ion beam source may be rotated to radiate from the opposite direction in case the bumps caused by the recesses and protrusions on the substrate is so large to cause shadow portions to the ion beam source, thereby providing sufficient orientation. In order to intentionally form such recesses and protrusions on the substrate when printing the orientation film in this exemplary embodiment, concentration of, for example, butyle-cellosolve solvent that is used as a leveling material for the orientation material may be set to lower than a predetermined threshold value or concentration of the primary orientation material may be set to higher than a predetermined threshold value.

### Second Exemplary Embodiment

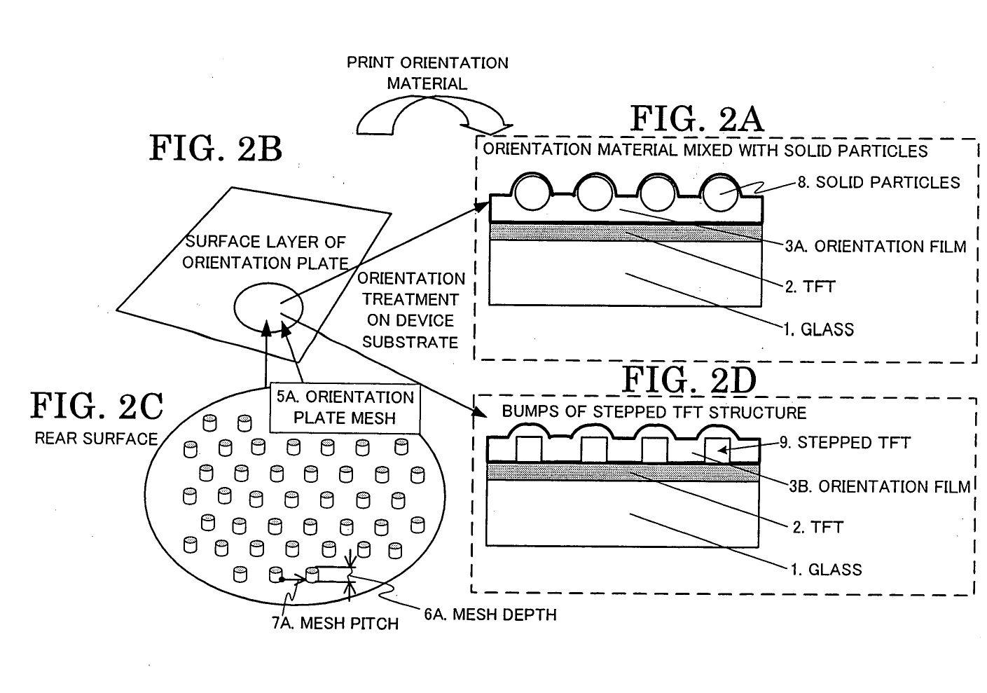

A second exemplary embodiment is a method of making recesses and protrusions on the surface of the orientation film by coating an orientation material mixed with solid particles on the substrate for liquid crystal display panel. FIG. 2 is a simplified illustration to show different examples of orientation film conditions for liquid crystal display panel that is made based upon the method of making liquid crystal display panel of this particular exemplary embodiment. FIG. 2 shows both liquid crystal display panels according to the second exemplary embodiment of roughing the surface of the orientation film by the orientation material mixed with solid particles and also a third exemplary embodiment for roughing the orientation film surface by employing recesses and protrusions structure of a TFT that will be described hereinafter.

FIG. 2 is a simplified illustration similar to the one that has been described hereinabove as the background art with reference to FIG. 3. FIG. 2(A) and (D) are cross section views of the liquid crystal display panel. FIG. 2(B) is a perspective view showing an orientation plate on which an orientation material is coated. FIG. 2(C) is a magnified view of the surface layer of the orientation plate for schematically showing a mesh pattern of the orientation plate. It is to be noted that FIG. 2(A) shows a cross sectional shape of the liquid crystal display panel of this exemplary embodiment. FIG. 2(D) shows a cross sectional shape of the liquid crystal display panel of the third exemplary embodiment that will be described hereinafter.

Now, a reference will be made on FIG. 2(A), (B) and (C) for describing the method of making substrate structure in this exemplary embodiment.

As shown in FIG. 2(A), the liquid crystal display panel of this exemplary embodiment forms a TFT 2 on a glass substrate 1 and then forms a 500-700□ thick orientation film 3A by coating an orientation material on the TFT 2 in the same manner as in FIG. 3(A). However, unlike the case in FIG. 3(A), an orientation material mixed with solid particles 8 is coated, thereby forming recesses and protrusions (uneven shape) on the surface layer thereof. Subsequently, similar to the first exemplary embodiment, the entire uneven surface of the orientation film 3A is radiated by an ion beam in a certain angle to reach the saturating condition. As for shadowing portions to an ion beam source, a radiation angle of the ion beam source is rotated to radiate from the opposite direction, thereby forming an ion beam radiation layer on all portions including the shadowing portions, thereby forming a 20-30□ thick ion beam radiation layer over the entire surface of the orientation film 3A.

As for the surface shape of the orientation plate onto which the ion beam is radiated, although a mesh shaped surface layer is formed on the surface of the orientation plate as an orientation plate mesh 5A that is shown in FIG. 2(B), it maybe the same structure as the orientation plate mesh 5C in FIG. 3. As shown in FIG. 2(C), a mesh depth 6A representing the height of the protruding portions of the orientation plate mesh 5A is shallow over the entire surface similar to the orientation plate mesh 5C and the mesh pitch 7A representing the distance between adjacent protrusions of the orientation plate mesh 5A is large similar to that of the orientation plate mesh 5C.

In other words, describing the orientation printing method with reference to FIG. 2, in order to form the orientation film 3A having recesses and protrusions on the liquid crystal display panel that comprises the glass substrate 1 and the TFT 2, an orientation material is coated on the substrate for liquid crystal display panel in a condition that contains solid particles 8 having a sufficiently small size relative to the cell gap. This increases the effective surface area of the surface layer of the orientation film 3A because recesses and protrusions are formed on the surface layer of the orientation film 3A.

It is to be noted that the surface condition of the solid particles 8 and surface tension and concentration of the orientation material are properly adjusted so that the surface of the solid particles 8 is sufficiently covered with the orientation material.

Since orientation condition by ion beam radiation saturates at a certain value relative to accumulated intensity of the ion beam radiation as described hereinabove, there is an upper limit in the orientation regulation force in the conventional method in which unevenness of the substrate surface is reduced. However, this exemplary embodiment in which recesses and protrusions are formed on the substrate is able to radiate the ion beam over the entire surface to reach the saturating condition similar to the first exemplary embodiment, thereby increasing the effective orientation surface area, increasing the orientation regulation force and providing the construction advantageous against long term residual image.

If there are large bumps (or steps) on the substrate created by the recesses and protrusions to shadow to the ion beam source and to prevent sufficient radiation of the ion beam, the radiation angle of the ion beam source may be rotated to radiate from the opposite direction. This enables to provide sufficient orientation performance.

### Third Exemplary Embodiment

A third exemplary embodiment applies a photo lithographic technology to the substrate for liquid crystal display panel that comprises a glass substrate, a TFT, a flat film and the like for forming recesses and protrusions on the surface layer of the TFT 2, and finally forming recesses and protrusions on a surface layer of an orientation film that is formed thereon. As described hereinabove in the second exemplary embodiment, FIG. 2(D) is a cross section view that illustrates the cross sectional shape of the liquid crystal display panel in this exemplary embodiment. FIG. 2(B) is a perspective view that illustrates the surface layer of an orientation film formed by printing an orientation material. FIG. 2(C) is a magnified view of the surface layer of an orientation plate and illustrates a mesh pattern of the orientation plate.

Now, reference is made to FIG. 2(D), (B) and (C) for describing the method of making a substrate structure in this exemplary embodiment.

As shown in FIG. 2(D), the liquid crystal display panel in this exemplary embodiment first forms a glass substrate 1 and a TFT 2 and then etching process is applied to the surface of the TFT 2 by a photo lithography technology for forming TFT bumps (or steps) 9. Subsequently, an orientation material is coated on the uneven surface of the TFT 2 having the TFT bumps 9 to form an orientation film 3B in the thickness of 500-700□. The orientation film 3B differs from the one in FIG. 3(A) in that the orientation film is coated on the TFT 2 having the TFT bumps 9, thereby forming recesses and protrusions on the surface layer of the orientation film 3B. Then, an ion beam is radiated on the entire uneven surface of the orientation film 3B at a certain angle to reach the saturating condition. As for shadowing portions to the ion beam source, the radiation angle of the ion beam source is rotated to form an ion beam radiation layer even on the shadowing portions. In this manner, the ion beam radiation layer in the thickness of 20-30□ is formed on the entire surface of the surface layer of the orientation film 3B.

It is to be noted here that the surface shape of the orientation film onto which the ion beam is radiated is a mesh-shaped structure like the orientation plate mesh 5A similar to the second exemplary embodiment as shown in FIG. 2(B) but it may take the structure like the orientation plate mesh 5C as shown in FIG. 3. As shown in FIG. 2(C), mesh depth 6A representing the height of protrusions of the orientation plate mesh 5A is shallow over the entire surface similar to the orientation plate mesh 5C and mesh pitch 7A representing the distance between adjacent protrusions on the orientation plate mesh 5A is large similar to the case in the orientation plate mesh 5C.

In other words, by referring to FIG. 2, the orientation printing method features in that recesses and protrusions are also formed on the surface layer of the orientation film 3B that is formed on the uneven pattern having recesses and protrusions on the flat film of the glass substrate 1, the TFT 2 and the transparent film or the like by applying a photo lithography technique, thereby increasing the effective surface area of the surface layer of the orientation film 3B. For example, areas for drains or gates of the TFT 2 are raised to define protrusions while areas for display pixels being recessed or flat to define recesses, thereby ultimately forming recesses and protrusions in the surface layer of the orientation film 3B when the orientation material is coated thereon.

Since the orientation condition by the ion beam saturates at a certain constant value with respect to accumulated intensity of the ion beam radiation as described hereinabove, there is an upper limit in the orientation regulation force in the conventional structure of the substrate surface with minimum unevenness or reduced recesses and protrusions. However, this particular exemplary embodiment in which recesses and protrusions intentionally formed on the substrate and the ion beam is radiated to the saturation value on the entire surface of the substrate enables to increase the effective orientation surface area, to increase the orientation regulation force and also to provide the structure advantageous against long term residual image.

It is to be noted here that, if bumps or steps of the recesses and protrusions on the substrate are large to shadow the ion beam source to such level that radiation of the ion beam is insufficient, the radiation angle of the ion beam source may be rotated to radiate from the opposite direction, thereby providing sufficient orientation.

Now, further description will be given on the abovementioned exemplary embodiments of this invention with reference to FIG. 1. Firstly, the mesh condition of the orientation plate in the first exemplary embodiment will be described. Although tuning of the orientation plate and the orientation material is made so as to reduce surface unevenness (recesses and protrusions) in the conventional orientation printing, mesh depth and mesh pitch of the orientation plate are made rough and also composition of the solvent is chosen to reduce leveling of the orientation material in the exemplary embodiment in order to intentionally leave recesses and protrusions in the orientation printing. After printing the orientation material in an uneven manner, a heat treatment is carried out promptly in order to harden the orientation film 3, thereby preventing the orientation film 3 from increasingly flattening with time. This leaves an uneven orientation film 3 having recesses and protrusions on the substrate of liquid crystal display panel. By radiating the ion beam to reach the saturating condition, effective orientation surface area is increased.

As described hereinabove, if recesses and protrusions cause large bumps on the substrate to develop shadows to the ion beam source, the radiation angle of the ion beam source may be rotated so as to radiate from the opposite direction.

On the other hand, in the second exemplary embodiment in which the solid particles 8 are mixed with the orientation material, the solid particles 8 are chosen to have a sufficiently small diameter than the cell gap of the orientation material and also the orientation material and the solid particles are mixed with an appropriate amount not to cause display irregularity. Additionally, as described hereinabove, surface condition and shape of the solid particles 8 and surface tension and concentration of the orientation material are adjusted so that the solid particles 8 are sufficiently covered with the orientation material.

Again, if recesses and protrusions cause large bumps to shadow the ion beam source and not to radiate the ion beam sufficiently, it is possible to rotate the radiation angle of the ion beam source so as to radiate from the opposite direction.

In case of the recesses and protrusions structure of the liquid crystal device layer or the TFT 2 like the third exemplary embodiment, for example, drain areas or gate areas are formed in a protruding structure while forming the pixel display areas in a recessed or flat structure. Alternatively, aground such as the glass substrate 1 or any other transparent film (either inorganic or organic transparent film) may be in form of recesses and protrusions. Although the height of protrusions is preferably as high as possible, it is limited to a certain value so that the ion beam can be effectively radiated on the surface of the orientation film 3B from a constant radiation angle that is determined by the direction of orientation.

Again, if bumps defined by the recesses and protrusions on the substrate are large to shadow the ion beam source, the radiation angle of the ion beam source can be rotated to radiate from the opposite direction as described hereinabove.

As apparent from the foregoing descriptions, this invention is able to effectively increase the orientation regulation force and ease to generate residual image because recesses and protrusions are formed in the ion beam radiation surface of the orientation film on the substrate in order to increase the radiation area per unit ion beam area on the orientation film and to improve the orientation regulation force.

Preferred exemplary embodiments of this invention have been described hereinabove. It should be noted, however, that these exemplary embodiments are noting but examples of this invention and should not interpret to restrict the scope of this invention. It is obvious for a person having an ordinary skill in the art to make various modifications on this invention best suited for particular applications without departing from the scope and spirit of this invention.

1. A method of making liquid crystal display panel including orientation processing by radiating an ion beam onto an orientation film made on a substrate for the liquid crystal display panel, comprising the steps of:
forming recesses and protrusions on the surface of the orientation film that is radiated by the ion beam; and
radiating the ion beam onto the entire surface of the orientation film having recesses and protrusions to reach the saturating condition;
thereby increasing the effective orientation surface area.

2. A method of making liquid crystal display panel of claim 1, wherein if there are large bumps on the surface of the orientation film onto which the ion beam is radiated to cause shadowed portions to an ion beam source, the ion beam is radiated to the shadowed portions from the opposite direction.

3. A method of making liquid crystal display panel of claim 1, wherein the orientation film is formed in a mesh structure having a mesh depth larger than a predetermined value and a mesh pitch larger than a predetermined pitch, an orientation material for forming the orientation film is chosen to have solvent composition that is easy to form recesses and protrusions on the surface, and recesses and protrusions are formed on the surface of the orientation film.

4. A method of making liquid crystal display panel of claim 1, wherein either solvent concentration of a leveling agent to be used for the orientation material is set to lower than a predetermined threshold value or concentration of the primary material composing the orientation material is set to higher than a predetermined threshold value.

5. A method of making liquid crystal display panel of claim 1, wherein recesses and protrusions on the surface of the orientation film are formed by mixing the orientation material for forming the orientation film with solid particles that are sufficiently smaller than a cell gap of the orientation material.

6. A method of making liquid crystal display panel including orientation processing by radiating an ion beam onto an orientation film made on a substrate for the liquid crystal display panel, comprising the steps of:
forming recesses and protrusions on the surface of the orientation film that is radiated by the ion beam; and
radiating the ion beam onto the entire surface of the orientation film having recesses and protrusions to reach the saturating condition to increase the effective orientation surface area;
forming recesses and protrusions on the surface of the orientation film by mixing the orientation material for forming the orientation film with solid particles that are sufficiently smaller than a cell gap of the orientation material;
adjusting the surface condition and shape of the solid particles and the surface tension and concentration of the orientation material that the surface of each solid particle is sufficiently covered with the orientation material.

7. A method of making liquid crystal display panel of claim 6, wherein a photo lithography processing is applied to a glass substrate, a liquid crystal device layer or a transparent film constituting the liquid crystal display panel to form bumps on the surface of the liquid crystal display panel, thereby forming recesses and protrusions on the surface of the orientation film that is formed on a substrate of the liquid crystal display panel.

8. A method of making liquid crystal display panel of claim 6, wherein a photo lithography processing is applied to a glass substrate, a liquid crystal device layer or a transparent film constituting the liquid crystal display panel to form bumps on the surface of the liquid crystal display panel, thereby forming recesses and protrusions on the surface of the orientation film that is formed on a substrate of the liquid crystal display panel, the etching process being applied so that drain areas or gate areas on a liquid crystal device layer constituting the substrate for the liquid crystal display panel being formed in a protruding structure and pixel display area being formed in a recessed or flat structure.

9. A liquid crystal display panel made by orientation processing that radiates an ion beam onto an orientation film that is formed on a substrate for liquid crystal display panel,
wherein the surface of the orientation film that is radiated by the ion beam is uneven to have recesses and protrusions, and the ion beam is radiated onto the entire surface of the uneven orientation film to reach the saturating condition.

10. A liquid crystal display panel of claim 9, wherein the orientation film is made in an orientation plate mesh structure to have a mesh depth deeper than a predetermined depth and a mesh pitch narrower than a predetermined pitch, and the orientation material to form the orientation film comprises a solvent composition that is easy to form recesses and protrusions on the surface.

11. A liquid crystal display panel of claim 9, wherein the orientation film is made from an orientation material mixed with solid particles that are sufficiently smaller than a cell gap of the orientation material.

12. A liquid crystal display panel of claim 9, wherein bumps are formed on a glass substrate, a liquid crystal device layer or a transparent film for forming a substrate of the liquid crystal display panel
